(19) United States
(12) Patent Application Publication
(10) Pub. No.: US 2023/0230566 A1
(43) Pub. Date: Jul. 20, 2023

(54) SIDE-TO-SIDE SWIVELLING GUITAR VOLUME PEDAL

(71) Applicant: Brian David Ogonowsky, Mountain View, CA (US)

(72) Inventor: Brian David Ogonowsky, Mountain View, CA (US)

(21) Appl. No.: 17/579,031

(22) Filed: Jan. 19, 2022

(51) Int. Cl. G10H 1/34; G10H 1/46

(52) U.S. Cl. CPC G10H 1/348; G10H 1/46; G10H 2220/265; H03G 3/3005

(57) ABSTRACT

Rather than a vertical see-saw type of volume pedal for a guitar, a foot-controlled volume pedal for a guitar has a foot pad that swivels in a generally horizontal arc around a pivot point. The foot pad has a pointer at its far end (away from the pivot point) that points to the volume numbers 0-10. The player's heel will generally be over, or close to, the pivot point, and the foot covers the pad or part of the pad. The pivot point comprises a rotatable shaft that is coupled to a smaller rotatable shaft of a conventional potentiometer, by friction, gears, or a belt, for controlling the volume into the guitar amplifier. The rotation ratio of the two shafts may be, for example, 6:1. The swivel arc may be large (e.g., 5-8 inches) so a precise volume can be set between 0-10.

### FIELD OF THE INVENTION

The invention relates to foot-controlled volume pedals between a guitar, or other electronic instrument, and an amplifier.

### BACKGROUND

Most guitar players, when playing for an audience, want to adjust their volume while playing. Since the player's hands are playing the instrument, the player usually uses a foot pedal to control the volume. A conventional foot pedal is described in U.S. Pat. No. 9,767,780, incorporated herein by reference. In such a conventional foot pedal, the pedal/volume is controlled by pressing either the toe down (for increased volume) or the heel down (for decreased volume) on a vertically pivoting foot pad, like a see-saw. The toe end of the pad is connected to the shaft of a rotary potentiometer in the pedal, and pivoting the pad turns the potentiometer shaft clockwise or counterclockwise. The guitar, or an effects circuit, plugs into an input of the potentiometer, and the output of the potentiometer is plugged into the input of an amplifier.

Such pedals work fine. However, since controlling the volume requires pressing vertically on the foot pad and the player is standing over the pedal, there is no visual way for the player to know how far the pad is pressed down. Further, there is only a small range of vertical distance between minimum and maximum volume, which makes it difficult to precisely control the volume without actually hearing the volume. Still further, the player must change his balance when controlling the pedal so as to not put too much weight on the controlling foot.

What is needed is a foot-controlled volume pedal that provides the player a visual indication of how loud the volume will be. Also what is needed is a volume pedal that has a wider range of movement so the player can better set a desired volume. In this way, the player may control the pedal to be at a precise position corresponding to the desired volume. Still further, what is needed is a volume pedal that allows the player to not shift his weight when controlling the volume.

### SUMMARY

Rather than a see-saw type of volume pedal for guitarists, a foot-controlled volume pedal has a foot pad that swivels generally horizontally in an arc around a pivot point. The foot pad has a pointer at its far end (away from the pivot point) that points to the volume numbers 0-10, which may be illuminated.

The player's heel will generally be over the pivot point, and the foot covers the pad or part of the pad. Thus, a generally horizontal pivoting around the player's heel controls the volume. The swivel may have an angular range of up to 90 degrees, and the span of the volume settings between 0-10 can extend up to 10 inches so a precise volume can be set between 0-10.

In one embodiment, the player's entire foot is on the pad. In another embodiment, the player's heel is on the floor, and the ball of the player's foot is on the pad. In either case, the player swivels the player's foot around the heel, so the player's weight can be still supported by the heel.

The pad is connected to a shaft at the pivot point and the shaft is coupled to the shaft of a potentiometer. The coupling may be by friction, gears, a belt, or other coupling. The pad shaft has a diameter much larger than the potentiometer shaft, so swiveling the pad less than 90 degrees rotates the potentiometer shaft over its full rotation of, for example, 300 degrees.

Other embodiments are envisioned.

### BRIEF DESCRIPTION OF THE DRAWINGS

FIG. 1 is a top down view of the foot-controlled volume pedal, also showing the placement of the player's foot over the foot pad.

FIG. 2 is a side view of the pedal and the player's foot on the top of the pad.

FIG. 3 illustrates a simple rotary potentiometer that is turned by the horizontal swiveling of the pad.

FIG. 4 illustrates a gearing configuration that results in a relatively small angular swivel of the pad causing a much larger angular turn of the potentiometer shaft so that the movement of the pad between volumes 0-10 over, for example, a 45 degree swivel results in a full rotation (e.g., 300 degrees) of the potentiometer shaft between zero volume and maximum volume.

FIG. 5 illustrates a volume pedal where an arm internal to the pedal is coupled between the foot pad and the pivot point (shaft) of the pad.

FIG. 6 is a side view of one of the embodiments of the pedal of FIG. 5, where the player's heel rests on the floor, and the ball of the player's foot swivels the pad. The pedal is wedge shaped.

FIG. 7 illustrates an embodiment where a swiveling arm extends beyond the pedal, and the player pushes against the side of the arm to swivel the arm above the pedal to control the volume. The player's foot is thus not over the pedal.

FIG. 8 is a side view of the pedal of FIG. 7.

Elements in the various figures that are the same or equivalent are labeled with the same numeral.

### DETAILED DESCRIPTION

A foot-controlled volume pedal 10 for a guitar or other electronic instrument has a horizontally swiveling foot pad 12 (also referred to as a controller). The foot pad 12 may be metal or plastic.

A shaft at a pivot point 14 supports the pad 12 over the pedal's base 16. The pad 12 may also include extra support at its far end, such as a roller. In one embodiment, the length of the pedal 10 is about the size of an adult foot, such as 12 inches.

The pedal 10 may be shaped like a wedge and can be very shallow, since all movement is horizontal and the circuitry is a simple potentiometer with two jacks for the guitar and amplifier.

At the end of the pad 12 is an indicator 18, such as a line or arrow that points to a range of volumes, such as 0-10, with 10 being the maximum volume and 0 being zero volume. The numbers may be illuminated such as by an LED backlight.

In the example, the swiveling of the pad 12 has a range of about 45 degrees. The range of volumes 0-10 may extend about 8 inches across for a pedal 10 that is about 12 inches in length. This greatly exceeds the range of a conventional see-saw volume pedal, whose volume range extends about 2-3 inches.

A dashed outline of the player's foot 20 is shown. Ideally, the player's heel will be generally over the pivot point 14, which results in a very comfortable control position for swiveling the pad 12. The pad and the shaft can be robust and generally supports the player's weight, so the player does not have to shift his weight to the non-controlling foot. If the pad 12 bends downward due to excessive weight, it will only contact the pedal's base 16 so no damage is done.

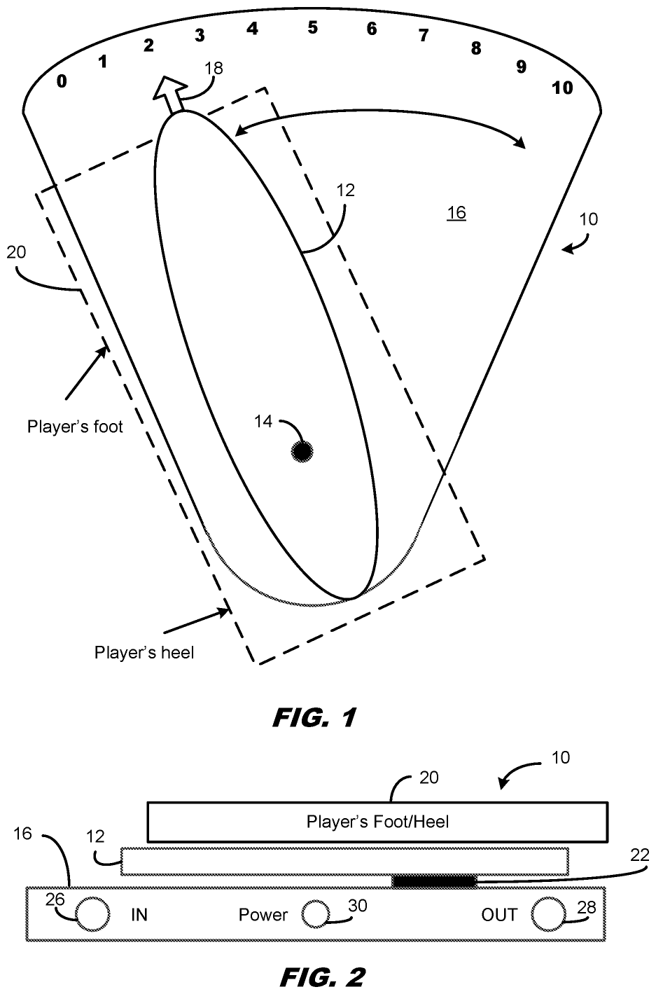

FIG. 2 is a side view of the pedal 10 which shows the rotating shaft 22 supporting the pad 12. The shaft 22 may be very robust since it does not need to be the shaft of the potentiometer.

The pedal 10 has a phono jack 26 for receiving a phono plug of a guitar wire (or effects box) input and a phono jack 28 for receiving a phono plug of a wire leading to the amplifier.

A power input 30 may be used to illuminate the volume indicators 0-10.

FIG. 3 is a schematic diagram of a conventional rotary potentiometer 36 that may be used in the pedal 10. A guitar 40 (or an effects box) is plugged into one input of the pedal 10 and is connected to two inputs 42/44 of the potentiometer 36. The potentiometer output 46/48 is connected to the input of an audio amplifier 50. The swiveling of the pad 12 turns the potentiometer shaft, which causes a metal contact 52 to move along a resistive element 54 (actually an arc-shaped resistive element) to select the percentage of the guitar electric output to be applied to the amplifier 50. The rotating contact 52 movement is directly related to the swiveling of the pad 12.

Since the full swivel arc of the pad 12 (e.g., 45 degrees for volumes 0-10) should equate to a full turning of the potentiometer shaft (e.g., 300 degrees for min to max volume), some gearing or other technique may be used.

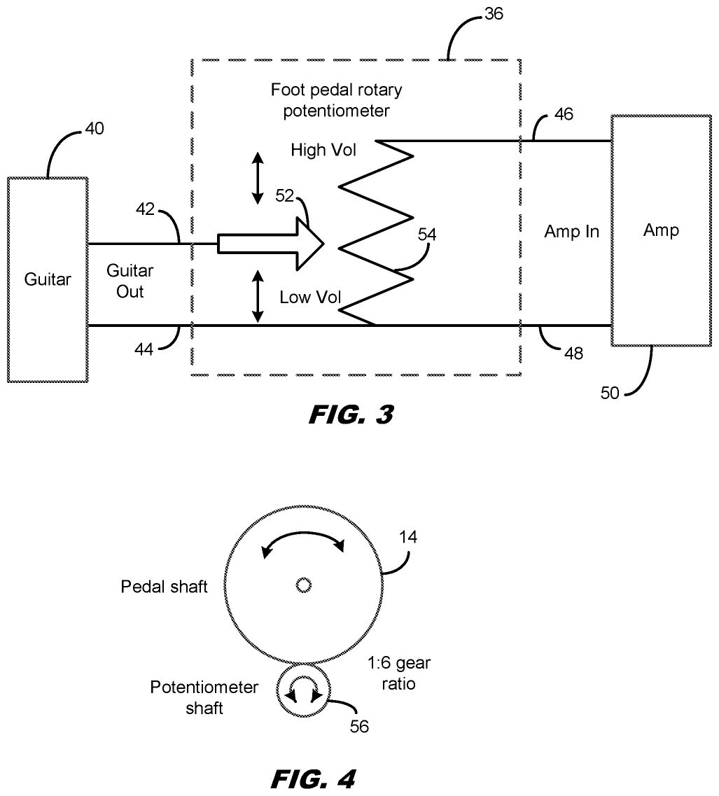

FIG. 4 illustrates how the shaft 14 of the pad 12 is coupled to a smaller shaft 56 of the potentiometer 36 for an approximate 6:1 turning ratio. The shafts 14/56 may be coupled using gears, friction, a belt, etc. The shafts 14/56 are generally vertical or otherwise perpendicular to the swiveling of the pad 12. The shaft 14 of the pad 12 may be fairly large and robust to support the pad 12 and the player's foot pressure.

Many other embodiments are envisioned where the foot pad swivels in a generally horizontal plane rather than the conventional vertical path, to give the guitarist a better visual indication of the position of the volume controller. The pedal 10 may be very flat, which makes it more transportable than the conventional pedal.

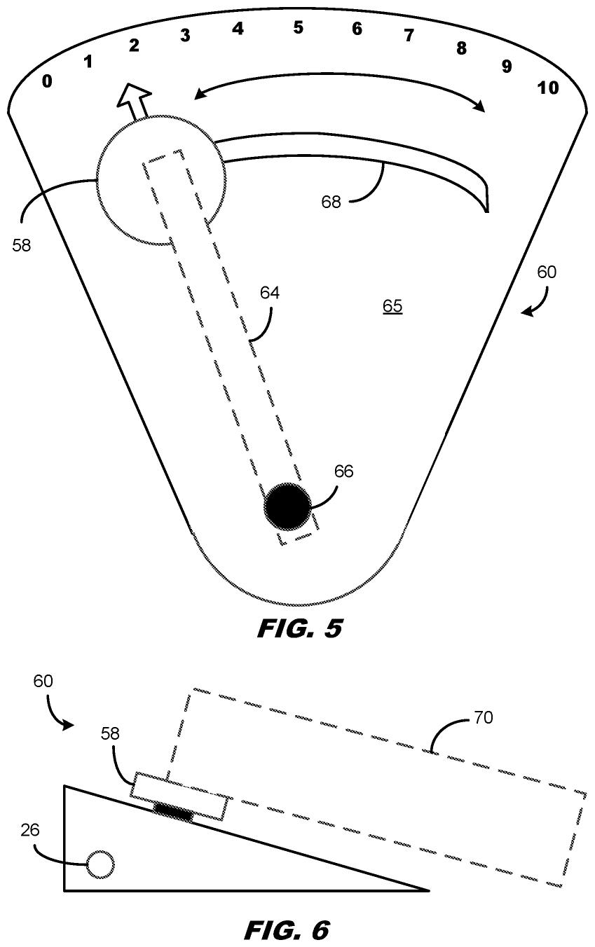

In another embodiment, such as shown in FIG. 5, the player's heel does not contact the movable pad 58 but may rest on the lower end of the pedal 60 or on the floor. The ball of the player's foot rests on a small pad 58, and the player swivels his foot to move the pad 58 in an arc. The pad 58 is attached to an arm 64. The arm 64 may be within the pedal 60 or above the base 65 of the pedal 60 and pivots around a shaft 66 that is internal to the pedal 60 or protrudes through the pedal base 65. A connector (not shown) between the pad 58 and the internal arm 64 moves through an arced slot 68 in the pedal base 65. The swiveling of the pad 58 turns the shaft 66 to turn the shaft of the potentiometer, as in FIG. 4, to control the volume.

The arm 64 connected to the shaft 66 may be flexible so the foot pressure cannot bend the shaft 66. A high foot pressure will simply press the pad 58 against the pedal surface without damage. The bottom of the pad 58 and the top surface of the pedal may have low friction so the pad 58 can slide along the surface of the pedal.

FIG. 6 illustrates a side view of one possible embodiment of the pedal 60 of FIG. 5, where the heel of the player's foot 70 contacts the ground as a pivot point, and the ball of the foot 70 moves the pad 58 in an arc. The pedal 60 is shaped like a wedge (in the side view) and is thus very compact. In such a case, the movement of the pad 58 is an angled arc rather than a horizontal arc. The heel may instead be supported by the surface of the pedal 60. The input and output jacks may be on opposite sides.

In the embodiments of FIGS. 1 and 5, the player may also swivel the pad by pushing on the sides of the pad.

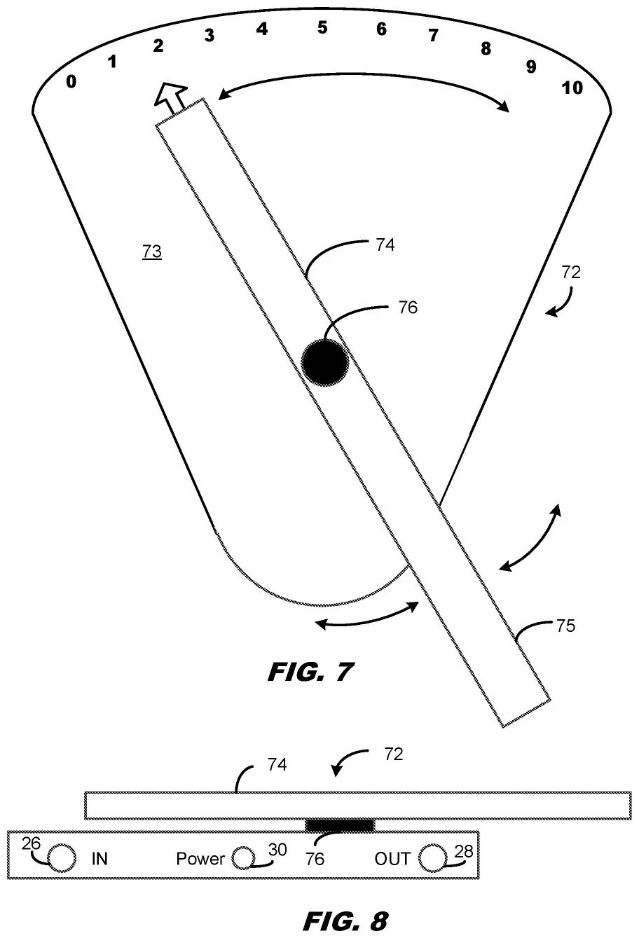

FIG. 7 illustrates another embodiment of a volume control pedal 72 where the player does not put his foot over the base 73 of the pedal. Instead, the player pushes against the end 75 of a swiveling arm 74 with the toe of his foot. The player's heel swivels against the ground, so the player does not have to shift any weight to operate the pedal 72. The arm 74 swivels around a shaft 76, which may be similar to the shafts previously described. Turning of the shaft 76 through its 45 degree range rotates the shaft of a conventional potentiometer in the pedal about 300 degrees (its min to max volume rotation) through appropriate gearing, belt, etc.

FIG. 8 is a side view of the pedal 72. The pedal 72 may be made very thin, such as one-half inch thick. The arm 74 can be any thickness since it does not support any weight. The arm 74 may even be a wire rod.

Importantly, the swiveling of the pad along an arc provides a clear indication, via the visible volume numbers 0-10, of the corresponding position of the potentiometer shaft and, thus, the volume into the amplifier. The volume may be precisely set due to a large range of movement of the pad. The pad's arc is similar to the arc of a player's foot swiveling about the heel so the player can still put all weight on the heel for support, unlike the conventional see-saw volume pedal.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

1. A foot-operated volume control pedal for an electronic instrument comprising:
an input for receiving a first signal related to an output of the electronic instrument;
an output for outputting a second signal for being amplified;
a variable resistive element within the pedal for controlling an electronic coupling between the input and the output for controlling volume, the resistive element having a rotatable first shaft; and
a side-to-side swiveling, foot-operated controller coupled to the first shaft of the resistive element, a position of the controller along a non-vertical arc corresponding to an amplified volume by the controller turning the first shaft of the variable resistive element through the arc.

2. The pedal of claim 1 wherein the input is a first phono jack for receiving a first phono plug.

3. The pedal of claim 2 wherein the output is a second phono jack for receiving a second phono plug.

4. The pedal of claim 1 wherein the variable resistive element comprises a potentiometer.

5. The pedal of claim 1 wherein the controller comprises a foot pad configured to rotate the first shaft of the restive element when the foot pad is swiveled about a pivoting second shaft.

6. The pedal of claim 5 wherein the first shaft and the second shaft are coupled together such that rotating the second shaft rotates the first shaft by a certain ratio.

7. The pedal of claim 1 wherein the pedal shows volume increments to a player, and the controller has an indicator that points to the volume increments.

8. The pedal of claim 7 wherein the volume increments are arranged in an arc corresponding to an arc of the controller as the controller is moved by a player.

9. The pedal of claim 1 wherein the controller swivels through a first arc, which rotates the first shaft of the resistive element.

10. The pedal of claim 1 wherein the controller is configured for a player to place the player's foot on top of the controller for swiveling the controller.

11. The pedal of claim 1 wherein the controller is configured for a player to swivel the controller by pushing the controller with the player's foot.

12. The pedal of claim 1 wherein the controller is large enough for a player's heel to rest on the controller while the player swivels the player's foot to swivel the controller.

13. The pedal of claim 1 wherein the controller is configured such that a player's heel rests on a top surface of the pedal, and the player contacts the controller with a ball of the player's foot to swivel the controller.

14. The pedal of claim 1 wherein the controller is configured such that a player's heel rests on a surface off of the pedal, and the player contacts the controller with a ball of the player's foot to swivel the controller.

15. The pedal of claim 1 wherein the pedal has a base, and wherein a first end of the controller extends beyond the base, the controller being configured for a player to push the first end of the controller with the player's foot to rotate the controller about a pivot point to rotate the first shaft for controlling the volume.

16. The pedal of claim 15 wherein the controller is configured such that no part of the player's foot is above the base of the pedal.

17. The pedal of claim 1 wherein the pedal has a wedge shape, as viewed from a side of the pedal.

18. The pedal of claim 1 wherein the side-to-side swiveling along the non-vertical arc comprises a horizontal swiveling.

19. The pedal of claim 1 wherein the side-to-side swiveling along the non-vertical arc comprises an angled swiveling.

20. The pedal of claim 1 wherein the pedal has a base with a slanted surface, wherein the controller is configured to move over the slanted surface from side-to-side in an angled arc by action of a player's foot.
